(19) United States
(12) Patent Application Publication
(10) Pub. No.: US 2022/0076987 A1
(43) Pub. Date: Mar. 10, 2022

(54) PIN-LIFTING DEVICE HAVING STATE MONITORING

(71) Applicant: VAT Holding AG, Haag (CH)

(72) Inventors: Adrian ESCHENMOSER, Grabs (CH); Michael DÜR, Hohenweiler (AT); Andreas HOFER, Widnau (CH)

(21) Appl. No.: 17/415,863

(22) PCT Filed: Dec. 13, 2019
(86) PCT No.: PCT/EP2019/085063

§ 371 Date: Jun. 18, 2021

(30) Foreign Application Priority Data
Dec. 19, 2018 (DE) 10 2018 009 871.1

(51) Int. Cl. H01L 21/687; G01P 15/18; G01P 15/02

(52) U.S. Cl. CPC H01L 21/68742; G01L 1/16; G01P 15/02; G01P 15/18

(57) ABSTRACT

Disclosed is a pin lifting device which is designed for moving and positioning a substrate to be processed, in particular a wafer, in a process atmosphere region which can be provided by a vacuum process chamber. The pin lifting device includes a coupling designed to receive a support pin adapted to contact and support the substrate, and a drive unit designed and interacting with the coupling such that the coupling is linearly adjustable along an axis of adjustment from a lowered normal position to an extended support position and back. The pin lifting device has at least one sensor unit which is designed and arranged in such a way that force-dependent and/or acceleration-dependent condition information can be generated by means of the sensor unit with reference to at least part of the pin lifting device.

The invention relates to a pin lifting device for moving and positioning a substrate in a process chamber, wherein the pin lifting device comprises a sensor for sensing an operating condition.

Pin lifting devices, also known as pin lifters, are typically designed and provided for the reception and defined positioning of a substrate to be processed in a process chamber. These are used in particular for vacuum chamber systems in the area of IC, semiconductor, flat panel or substrate production, which must take place in a protected atmosphere without the presence of contaminating particles.

Such vacuum chamber systems comprise in particular at least one evacuatable vacuum chamber which is provided for receiving semiconductor elements or substrates to be processed or produced and which has at least one vacuum chamber opening, through which the semiconductor elements or other substrates can be guided into and out of the vacuum chamber. For example, in a production plant for semiconductor wafers or liquid crystal substrates, the highly sensitive semiconductor or liquid crystal elements pass sequentially through several process vacuum chambers in which the parts located within the process vacuum chambers are each processed by means of a processing device.

Such process chambers often have at least one transfer valve whose cross-section is adapted to the substrate and the robot and through which the substrate can be introduced into the vacuum chamber and, if necessary, removed after the intended processing. Alternatively, a second transfer valve may be provided through which the processed substrate is removed from the chamber.

The substrate, e.g. a wafer, is guided, for example, by a suitably designed and controlled robot arm, which can be guided through the opening in the process chamber provided by the transfer valve. The process chamber is then loaded by gripping the substrate with the robot arm, introducing the substrate into the process chamber and depositing the substrate in the chamber in a defined manner. The process chamber is emptied accordingly.

For the placement of the substrate and for the exact positioning of the substrate in the chamber, a relatively high accuracy and mobility of the substrate must be ensured. For this purpose, pin lifting systems are used which provide a plurality of support points for the substrate and thus a load distribution (due to the dead weight of the substrate) over the entire substrate.

The pins are preferably in a receiving position and the robot places the substrate on the pins in this position. Alternatively, the substrate can be brought into position by means of the robot over the support pins of the lifting device and lifted by the pins. After the robot has moved away, the substrate is deposited by lowering the pins on a carrier, e.g. a potential plate, and the robot arm, which typically carries the substrate, is moved out of the chamber, e.g. at the same time as the substrate is deposited. The pins can be lowered further after depositing the substrate and are then present separated from it, i.e. there is no contact between the pins and the substrate. After removing the robot arm and closing (and introducing process gas or evacuating) the chamber, the processing step is performed.

A low force effect on the substrate is particularly important after the process step has been carried out in the chamber and when the substrate is subsequently raised, as the substrate can adhere to the carrier, for example. If the substrate is pushed away from the carrier too quickly, the substrate may break, as the adhesive forces cannot be overcome or resolved at least at certain contact points. In addition, even if contact is established between the support pins and the substrate, any impact with the substrate can lead to undesired stress (or breakage).

At the same time, in addition to the gentlest possible and careful treatment of the substrates to be processed, the shortest possible processing time should also be made possible. This means that the substrate can be brought into the defined conditions—loading and unloading position and processing position—in the chamber as quickly as possible.

To avoid unwanted shocks during the processing of semiconductor wafers, for example, U.S. Pat. No. 6,481,723 B1 recommends the use of a special stop device instead of hard motion stops in a pin lifter. Any hard plastic stops should be replaced here by a combination of a softer designed stop part and a hard stop, wherein the contact with the soft stop part is first made for the limitation of movement and then the hard stop is brought into contact with the soft stop part and damped accordingly.

U.S. Pat. No. 6,646,857 B2 proposes a regulation of the lifting movement by means of a recorded occurring force. The lifting pins can be moved as a function of the force signal received so that the lifting force at the lifting pins is always applied to the wafer in a controlled and dosed manner.

With each machining cycle, the support pins are brought into contact with the substrate to be received and released from it. This naturally results in corresponding mechanical stresses (e.g. shocks) on the pins and the drive. The machining cycles are often timed in a comparatively tight manner and require a relatively short process time. A large number of repetitions in a comparatively short time can be the result of this process implementation. Typically, the support pins are therefore regarded as wear material and require regular replacement, i.e. they usually have to be replaced after a certain number of cycles or a certain operating time.

Accordingly, a motor of a mechatronically designed pin lifter, i.e. a pin lifter with an electric motor for adjusting the pin, is increasingly stressed.

Naturally, a part of such a pin lifting device is connected to a process volume (process chamber), e.g. the pin lifting device is flanged to the process chamber. Typically, such a connection influences the various conditions of the chamber (e.g. temperature, potential) according to the condition of the pin lifting device.

The above-mentioned external influences on a pin lifting device can lead to an impairment of the operation up to the failure of the device. To avoid this, the pin lifts are maintained or replaced as a precaution at regular intervals or after a certain number of operating cycles or after a certain period of operation.

A remaining disadvantage, however, is that even if the pin lifter is replaced or serviced at regular intervals, it may deviate from its normal functionality for a certain period of time before maintenance and thus lead to faulty production cycles. Furthermore, the previous maintenance approach does not allow an optimal maintenance time to be determined, but only a regular maintenance time, which means, for example, that the pin lifter can be replaced earlier than would be technically necessary. The maintenance or renewal of such elements usually requires a standstill or interruption of production processes and a more or less massive intervention in the overall system. This often leads to comparatively long downtimes.

It is therefore the object of the present invention to provide an improved pin lifting device which reduces or avoids the above disadvantages.

In particular, it is the object of the invention to provide an improved pin lifting device which enables an optimized, i.e. in particular predictive and highly precise, maintenance of the device.

It is another special object of the invention to provide a pin lifting device which enables a monitoring of the own functionality and/or a superior process functionality.

These objects are solved by the realization of the characteristic features of the independent claims. Features which further develop the invention in an alternative or advantageous way can be found in the dependent claims.

The invention relates to a pin lifting device, in particular a pin lifter, which is designed to move and position a substrate to be processed, in particular a (semiconductor) wafer, in a process atmosphere region which can be provided by a vacuum process chamber. The pin lifting device comprises a coupling adapted to receive a support pin adapted to contact and support the substrate, and further comprises a drive unit adapted to cooperate with the coupling such that the coupling is linearly adjustable along an adjustment axis. The adjustability of the coupling can be shifted from a lowered normal position, which is defined in particular for providing the support pin in a substantially ineffective condition (no contact with the substrate) with respect to its intended effect (e.g. moving, carrying and positioning of a workpiece or substrate), to an extended support position, which is adapted in particular for providing an intended effect of receiving and/or providing the substrate by the support pin, and back.

The intended effect of the support pin is essentially understood to be a receiving, contacting, moving, carrying and/or positioning etc. of a workpiece or substrate. In this context, an ineffective condition of the support pin is to be understood as a condition in which the pin is contactless (not yet or no longer in contact) with a substrate to be contacted as intended and in particular temporarily does not provide the intended purpose, e.g. is in a lowered waiting position. This is particularly the case while a machining process is being performed on the substrate. However, the provision of the intended effect does not exclusively mean that there is contact between the support pin and the substrate; rather, the pin can be present in this condition in an extended condition and held ready for the reception of a wafer (placement of the wafer on the pin). The processes or movements (transport of the wafer) that occur as a result of contact are also to be understood as providing the intended effect.

An unloaded receiving condition represents a condition in which a support pin to be picked up is not in a held target position relative to the coupling (in the coupling). A loaded condition is to be understood as a condition in which the support pin is held by the coupling in a received target position. It is understood that the invention also extends to the pin lifting device without a coupled support pin.

The pin lifting device also has at least one sensor unit which is designed and arranged in such a way that force-dependent and/or acceleration-dependent condition information with reference to at least part of the pin lifting device can be generated by means of the sensor unit.

By means of the sensor unit, inertia effects, accelerations of parts or the entire pin lifting device and/or external influences, such as a (weight) force acting on the coupling, can be detected. Such effects may be caused by the operation of the device itself, e.g. vibrations or (inherent) vibrations from the drive unit, or may be external in nature, e.g. mechanical effects (shocks, dynamic effects of peripheral components etc.) from a connected component or device such as the process chamber.

In one embodiment, the pin lifting device has a separating device for separating the process atmosphere region from an external atmosphere region, wherein the drive unit is at least partially, in particular completely, associated with the external atmosphere region and the coupling is in particular at least partially associated with the process atmosphere region. The separating device is designed in particular as a bellows which is arranged in the inner volume of a coupling part which at least partially surrounds the coupling in the lowered condition. The separating device of the pin lifting device can also be formed by a housing of the drive unit.

The drive unit can be designed as an electric motor, in particular a stepper motor, which provides a mechatronic pin lifting device.

The drive unit can alternatively be designed as a pneumatic drive cylinder.

In one embodiment, the sensor unit may comprise at least one of the following inertial sensors for generating the acceleration-dependent condition information or be designed as such:

an acceleration sensor which detects accelerations along at least one axis aligned in a defined manner, in particular multi-axis accelerations,

a rotation rate sensor which detects rotational speeds or rotational accelerations about at least one axis aligned in a defined manner, in particular multi-axially ones,

a vibrometer, and/or

a sensor based on MEMS technology (microelectromechanical system).

Inertial sensors, in particular acceleration sensors, enable the detection not only of linearly directed and/or low-frequency acceleration events, but also the detection of high-frequency accelerations such as vibrations and dynamic natural oscillations of system components. From such measurement data further information can be obtained regarding the condition of a pin lifting device or the behavior of this device during operation. This, in turn, can be used to derive findings regarding desired process safety or a general statement as to whether a process is running within the framework of specified conditions.

In a particular embodiment, the sensor unit may comprise at least one of the following force sensors for generating the force-dependent condition information or be designed as such:

a pressure sensor,

a deformation-sensitive element, in particular a strain gauge,

a piezo force transducer with a piezo ceramic element,

an electrodynamic force transducer,

a resistive force transducer,

a vibration force transducer and/or

a spring body force transducer.

A force sensor provides for the detection of corresponding influences, e.g. a pressure arising from the depositing of a wafer, on the pin lifting device. A force measurement and in particular regulation of the pin movement on the basis of a currently recorded force signal can, for example, be implemented to avoid excessive forces on the wafer. For example, this can be used to control a continuous increase in force.

The sensor unit can be arranged according to a further embodiment of the pin lifting device according to the invention

on the coupling, in particular on a receptacle for the support pin,

on the drive unit, in particular on a spindle or a motor of the drive unit,

on a coupling element which provides the interaction of the drive unit with the coupling, in particular a threaded rod,

on the support pin and/or

on a housing of the pin lifting device, in particular on an underside or on an inner wall of the housing.

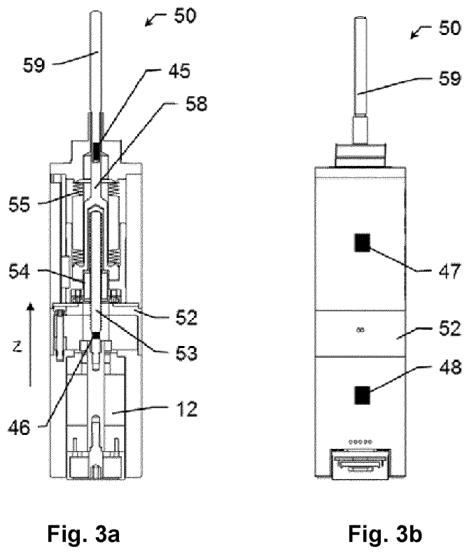

The invention also relates to a system consisting of a pin lifting device from above or as described in FIGS. 2a-3b and a processing and control unit. The processing and control unit is arranged and designed for receiving and/or processing the condition information of the sensor unit and for generating and/or outputting a condition-information-dependent output.

The processing and control unit thus provides processing and analysis functionality for measurement data that can be captured with the sensor unit. The processing and control unit can be connected in a wired or wireless manner to the pin lifting device for data exchange for this purpose.

Furthermore, the processing and control unit can be used for closed-loop control (regulation) of the pin lifting movement on the basis of recorded, processed and/or analyzed measurement data. For example, the continuous application of a constant force can be adjusted over a certain moving distance.

In one embodiment, the processing and control unit may be arranged to provide, by means of processing the condition information, the output relating to a current condition or relating to a current normal condition deviation of the drive unit and/or the coupling, in particular visually or acoustically. In particular, the output can be generated by means of an actual/target comparison for the acquired condition information.

The output can be intended and configured for the generation of information to a user, for example a production plant. It can alternatively or additionally also provide an input variable for a regulating circuit (regulator). In addition, the output can also serve as a control variable and provide direct actuation of the drive unit depending on a current condition.

In particular, the output can be generated as an output signal.

In particular, the output provides processed condition information. In particular, pure measurement data that can be generated by a sensor can be understood as condition information. These measurement data thus represent a condition of the device at the time of the measurement. If, for example, this information is related to a reference value, this comparison can identify and quantify a relative change.

The output can be provided with respect to mechanical and/or structural integrity of the drive unit and/or coupling. On the basis of the condition information (e.g. by comparison with a threshold value or a condition curve), a possible impairment of the system can be determined and the output with reference to the system integrity or system function can be generated accordingly.

In particular, the output may include one or both of the following:

a warning of increased wear of a component of the pin lifting device, and/or

a prediction of the durability of a component of the pin lifting device.

In particular, the processing and control unit may be adapted to provide a frequency spectrum (as the output) based on the condition information. Especially for the acquisition of acceleration information, such an evaluation of the measurement data can be a suitable basis for further processing or further use of the data. Certain frequencies or frequency ranges can be assigned to certain acceleration events or associated system components.

Thus, the processing and control unit may be designed in one embodiment to provide, based on an analysis of the condition information with respect to one or more measured value frequencies, the output with respect to a localization of an oscillation causing the respective measured value frequency.

The processing and control unit may be adapted to provide the output relating to an evaluation of a process performed with the pin lifting device based on a comparison of the condition information with a predefined reference value. By evaluating the information acquired by the sensor unit, a production step (e.g. coating process) can be monitored. If a measured acceleration or force information deviates from a target value (especially incl. tolerance), this can be an indication for a faulty lifting of a wafer from a support (de-chucking) under excessive force and cause damage to the wafer, for example.

According to a specific embodiment, the processing and control unit can be designed to derive a condition trend (in particular as the output), in particular a long-term trend, for a system condition and/or a change in the system condition based on a multiple acquisition of the condition information, in particular wherein the condition information is acquired periodically, in particular continuously, during a specific period of time and a frequency spectrum and/or a force-displacement ratio is derived.

As a result of such an evaluation of sensor data, a change in the function of the pin lifting device can be monitored and detected. Thus, long-term observation not only allows the acquisition of snapshots of the system but also the derivation of trends and the prediction of further condition changes.

In one embodiment, the processing and control unit can be designed to provide a calibration of the sensor unit and/or a monitoring of the sensor-unit-independent condition information based on a comparison of a currently detected condition information with further sensor-unit-independent condition information, in particular motor current of the drive unit.

By generating condition information for a specific measurement event from two different measurement sources, i.e. the sensor unit and further sources, a comparison of this information can be performed and the measurement systems can be mutually calibrated or monitored.

The processing and control unit can in particular be designed to detect, by means of the sensor unit, during an extension movement of the coupling equipped with a support pin into the support position, a change in condition, in particular an increase in force due to contacting of the substrate and/or acceleration course on the support pin, and to link it in particular to an extension position.

For example, a force-displacement diagram can be recorded and stored for a specific process. Deviations can be determined here with reference to a covered distance and/or a measured force. Alternatively or additionally, a contact point can be derived on the basis of a force or acceleration curve, i.e. an extension position for the pin at which contact with a substrate occurs.

In particular, the sensor unit can be designed and arranged in such a way that acceleration occurring in the drive unit and/or acting from the outside on the pin lifting device can be detected as condition information. For a detection with respective location reference, the sensor unit is preferably arranged at a suitable position of the pin lifting device, e.g. at the housing or the drive unit.

In a specific embodiment, the sensor unit can be designed and arranged in such a way that acceleration can be detected as condition information, which acceleration is produced by frictional vibration at at least one of the following locations:

between at least a part of the coupling and a guide and/or a bearing for the coupling,

between at least a part of the coupling and at least a part of the drive unit, and/or

between at least a part of the drive unit and a guide and/or bearing for the drive unit.

By detecting vibrations caused by friction, conditions such as wear of bearings or lubrication between two elements moving relative to each other can be detected. A signal analysis can also be used to differentiate possible vibration sources and thus achieve localization of said sources.

The condition information may, in particular, include at least one of the information listed below:

a force acting on the coupling and/or the support pin, in particular generated by the weight of a substrate resting on the support pin,

a force acting on the drive unit, in particular on a drive shaft or a motor of the drive unit,

an acceleration generated at the coupling and/or the pin,

an acceleration generated at the drive unit, and/or

an acceleration condition or a change in acceleration of the pin lifting device.

In one embodiment, the processing and control unit may be adapted to generate and output a control signal based on the condition information. The drive unit can also be arranged and designed to receive the control signal and to adjust the coupling between the normal position and the support position depending on the control signal. In other words, the system can be set up in such a way that the control of the drive is based on recorded measured values (open-loop or closed-loop).

In particular, the processing and control unit can be set up in such a way that the control signal can be set automatically as a function of current condition information. By continuously adjusting the control signal, a regulation of the pin lifting operation can be set up and, for example, an adjustment speed can be set as a function of a measured contact force.

Such a configuration enables the pin lifter to be controlled and/or regulated on the basis of currently acquired force or acceleration information. This allows the control of the drive unit to be adjusted, especially continuously or in real time, in such a way that effects such as strong vibration, for example, which can influence a machining process, can be compensated. Such compensation can therefore be implemented without structural intervention in the system only by adjusting the control system.

Another embodiment example can be as follows. If, for example, a significant, periodic or selective exceeding of a predefined target amplitude for a dynamic oscillation in the drive unit is detected, this may indicate a need for early maintenance of the drive. This information can be used on the one hand to adjust the control of the pin lifting device so that it is operated with a lower load (and possibly slower) and on the other hand to output the corresponding information for maintenance.

The devices according to the invention are described in more detail below by way of example by means of concrete embodiment examples schematically shown in the drawings, wherein further advantages of the invention are also discussed, wherein:

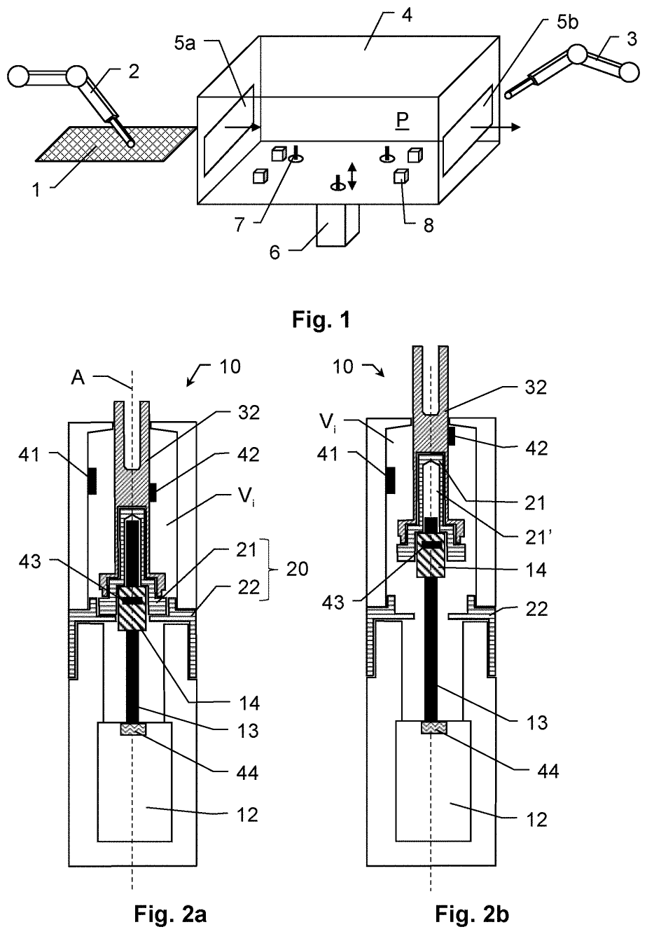

FIG. 1 shows a schematic representation of an embodiment of a vacuum processing device for a wafer with a lifting device according to the invention;

FIGS. 2a-b show an embodiment of a pin lifting device according to the invention; and

FIGS. 3a-b show a further embodiment of a pin lifting device according to the invention.

FIG. 1 schematically shows a process setup for processing a semiconductor wafer 1 under vacuum conditions. The wafer 1 is inserted into a vacuum chamber 4 (process atmosphere region P) by means of a first robot arm 2 through a first vacuum transfer valve 5a and brought into position by means of support pins 7 of pin lifting devices according to the invention (shown here: three pins). The wafer 1 is then picked up by the pins 7 or placed thereon and the robot arm 2 is moved away. The wafer 1 typically rests on the robot arm or a support device provided on the robot arm 2, 3 or is held by a specific support. After wafer 1 has been picked up by pins 7, the robot arm is guided out of chamber 4, transfer valve 5a is closed and pins 7 are lowered. This is done by means of the drives 6 of the pin lifting devices which are coupled to the respective pins 7. The wafer 1 is thereby placed on the four support elements 8 shown. Alternatively, the wafer 1 is placed on an electrostatic clamping device (not shown), a so-called electrostatic chuck, and held by applying an electrical voltage between the chuck electrodes and, optionally, leveled by the forces acting thereby. Currently, electrostatic chucks are typically used for the production of semiconductor wafers under vacuum conditions.

In this tightly held condition, a planned processing (e.g. coating) of the wafer 7 takes place under vacuum conditions and especially in a defined atmosphere (i.e. with a certain process gas and under defined pressure). Chamber 4 is coupled to a process gas source, a vacuum pump and preferably a vacuum regulating valve for regulating the chamber pressure (not shown).

After processing, the wafer 1 is lifted into a removal position again by means of the pin lifting devices. With the second robot arm 3, wafer 1 is subsequently removed through the second transfer valve 5b. Alternatively, the process can be designed with only one robot arm, with loading and unloading then taking place via a single transfer valve.

A pin lifter arrangement can alternatively (not shown) be designed as a ring lifter, i.e. formed or designed in a ring-shaped manner.

FIG. 2a shows an embodiment of a pin lifting device 10 according to the invention. The pin lifting device 10 has a drive unit 12 designed as an electric motor, which is assigned to a lower drive part of the device 10. Motor 12 is coupled to a threaded spindle 13. The threaded rod 13 can be rotated by actuating the motor 12 accordingly.

In addition, an adjustment element 14 is provided, which in the embodiment shown is designed as a slide 14, which interacts with the threaded rod 13 and can be moved linearly along a central adjustment axis A by rotation of the rod 13. The slide 14 has an internal thread which corresponds to the thread of the threaded rod 13. In addition, the slide 14 is mounted in such a way that it cannot be rotated relative to the pin lifting device 10 itself, but can only be moved in the directions of movement parallel to the adjusting axis A.

In the embodiment shown, the pin lifting device 10 has an insulating component 20, but it is understood that the present invention is not limited to pin lifting devices with such an insulating component 20, but rather includes pin lifting devices without such insulation. The slide 14 here is coupled to a first part 21 of the insulating component 20, which is movable relative to the drive unit 12. Analogous to the above, it is understood that slide 14 can alternatively (not shown) be coupled directly to coupling 32 and that coupling element 21 is omitted. The coupling element 21 can be moved and positioned linearly by the slide. The insulating component 20 also has a second part 22, a fixing element 22, fixedly connected to the drive part 11. This is also optional and may be missing in alternative embodiments. Both the coupling element 21 and the fixing element 22 are manufactured in such a way that they are unable to provide electrical conductivity. In particular, the coupling element 21 and/or the fixing element 22 is made of an electrically non-conductive material, e.g. plastic (e.g. PEEK) or coated with a non-conductive material.

The fixing element 22 is in turn firmly connected to a housing of an upper coupling part of the pin lifting device 10. An internal volume Vᵢ of the coupling part is defined by the housing. The coupling part has a movable coupling 32, the first end of which is designed to accommodate a support pin (support pin not shown). In the example shown, the coupling extends essentially along axis A. The coupling 32 is connected (at its lower part opposite the first end) to the coupling element 21 of the insulating component 20. In this example, the coupling 32 has an inner recess for this purpose in which the coupling element 21 is accommodated and fixed, e.g. by means of a glued or screwed joint.

By means of the connections between slide 14, coupling element 21 and coupling 32, a controllable movement of coupling 32 and thus of a support pin accommodated in coupling 32 can be provided by motor 12. Due to the coupling element 21 of the insulating component 20, a thermal and galvanic separation is also provided between the support pin and drive 12.

FIG. 2a shows the coupling 32 of the pin lifting device 10 in a lowered normal position, in which an optionally provided support pin would be present in an essentially ineffective condition with regard to its intended effect. In the case of providing the pin lifter 10 in a vacuum machining process, the support pin typically has no contact with a substrate to be machined.

FIG. 2b shows the coupling 32 of the pin lifting device 10 in an extended support position in which a coupled pin provides its intended effect of picking up, moving and/or providing the substrate.

To reach the extended support position, the motor 12 can be actuated accordingly. For this purpose, for example, a running time of the motor or a number of rotations to be carried out for the threaded rod 13 can be stored in order to set a desired position for the slide 14. In particular, an encoder is coupled to the drive unit 12 so that the movements of the motor axis can be monitored and regulated.

The linearly movable parts of the pin lifter 10, i.e. the slide 14, the coupling element 21 and the coupling 32, are mainly moved in the area of the upper coupling part. The slide 14 and the coupling element 21 move at least essentially within the inner volume Vᵢ. In the embodiment shown, the coupling element 21 is sleeve-shaped and provides a recess 21′ defined by the shape of the element 21. This recess 21′ allows a variable extension of the threaded rod 13 into the coupling element 21 and thus a translational mobility of the coupling element 21 relative to the threaded rod 13.

The two elements 21, 22 of the insulating component 20 thus provide a thermal separation between drive part 11 with drive unit 12 and the housing of the coupling part arranged in a fixed position in relation thereto. Secondly, a permanent thermal separation is also provided for the moving parts of the lower drive part and upper coupling part, i.e. between the coupling 32 and the slide 14.

Also an electrically conductive contact between individual components of the drive part and respective components of the coupling part can be prevented by means of the insulating component 20 independent of a condition of the pin lifter.

In the lowered normal position, the coupling element 21 and the fixing element 22 are preferably in contact.

The pin lifting device 10 has four sensor units 41-44 in the embodiment shown. It is understood, however, that the invention is not limited to an embodiment with four sensor units, but rather that embodiments with at least one such sensor unit are also included by the invention.

The sensor units 41-44 are each designed for the acquisition of acceleration information as condition information. At least one of the sensor units 41-44 is preferably designed as a multi-axis acceleration sensor. In an alternative embodiment, one or more of the sensor units 41-44 can be designed as a force sensor. In particular, the following measurement options and evaluation approaches can be transferred partially to the use of a force sensor.

The sensor units 41-44 are in communication connection with a processing and control unit (not shown), e.g. wirelessly via WLAN or Bluetooth, i.e. measurement data acquired with the sensors 41-44 are transmitted to this processing and control unit and further processed as required. The processing and control unit together with the pin lifting device forms a corresponding system. In particular, the processing and control unit may be designed as a structurally separate unit or installed in integrated form with the pin lifting device.

A first of the sensor units 41 is arranged in the inner volume Vᵢ on the inner wall of a housing of the upper coupling part and thus provides, for example, the recording of acceleration events which act externally on the pin lifting device 10. In this way, especially mechanical shocks to the pin lifter 10 can be registered. Furthermore, by monitoring a signal amplitude that is linked thereto, a magnitude of the shock can be determined and the probability of damage to the pin lifter caused by this can be evaluated. Such an approach can also be used, for example, to carry out transport monitoring. In addition to external influences, the sensor 41 can also detect vibrations of the pin lifter 10 caused, for example, by a movement of the coupling 32 and make them available for further evaluation.

A second sensor unit 42 is arranged on the coupling 32 and thus enables the direct detection of accelerations of the coupling 32, i.e. on the one hand a desired movement of the coupling 32 along axis A and/or on the other hand vibration occurring at the coupling 32. Such vibration can be caused in particular by the excitation of one or more system components according to their natural frequency spectra. The excitation or transmission of an oscillation can be caused by an operation of the motor 12.

Alternatively or additionally, a vibration of the coupling 32 can occur due to occurring friction between the coupling 32 and e.g. the housing or a guide (bearing) for the coupling 32 when the coupling moves.

The processing and control unit can be configured in such a way that a respective frequency spectrum can be derived from the acquired acceleration data. Such a spectrum can also be used to differentiate between individual acceleration events. A frequency spectrum that can be assigned to a friction differs from a spectrum that is generated, for example, by an alternative excitation. Thus, algorithmic evaluation can be used to determine whether a detected oscillation is caused by friction between two components or by other active excitation. This enables targeted maintenance of the pin lifting device, i.e. an affected component can be identified and replaced. As an example, the functionality of a bellows preferably provided in the pin lifting device 10 (not shown), which provides an atmospheric separation between the process atmosphere P (vacuum) and an ambient atmosphere (e.g. room air), can be monitored. By comparison with a known reference vibration profile, it is also possible to determine whether a vacuum is present inside the bellows (=nominal condition) or not by comparing the vibrations and oscillations that occur.

Furthermore, the quality, i.e. in particular the strength, of the occurring acceleration can be classified and, in connection with the particular type of acceleration, its effect on the condition of the pin lifting device can be assessed.

Depending on the possible effect on the pin lifting device, an output can also be made to a user. Alternatively, the output or an output signal can be transmitted to the drive unit and the drive control can thus be adapted. Appropriate countermeasures can dampen any vibrations that occur or, for example, largely avoid them by generating a suitable counter signal that prevents the excitation of a natural frequency.

The sensor unit 42 can also detect any relative movements of a substrate (wafer) resting on the support pin. If the wafer is moved in a lateral direction transverse to the adjustment axis A, accelerations in this direction caused by friction could be measured with the sensor 42 (or with one of the other sensors 41, 43, 44). If such an unwanted movement occurs, the formation of particles, e.g. through abrasion, can be a consequence. Particle formation is always critical during coating processes in the vacuum area and can lead to contamination of the process volume and thus to a strongly negative impairment of a production process. The provision of an accelerometer according to the invention can—as described—provide a monitoring system for such cases and thus, for example, issue a warning signal for such an event.

A further sensor unit 43 is arranged on the slide 43 and in particular provides direct condition information when the coupling 32 is moved along the adjustment axis A. Vibrations caused by a rotation of the spindle 13 and the resulting movement of the slide 43 can be picked up directly. The characteristic of the vibration that can be detected in this way makes it possible to evaluate the functional condition of the drive system. For example, the recorded vibration can be used to draw conclusions about the sliding ability or the condition of the lubrication between threaded rod 13 and slide 43. This conclusion can be drawn, for example, by comparing a reference frequency spectrum, which represents the target motion properties of the slide, with a currently acquired frequency spectrum. Alternatively or additionally, an amplitude that is increased relative to a reference value can indicate inadequate lubrication of the gear unit.

A fourth sensor 44 is arranged on the motor 12. This allows vibration and oscillations of the motor 12 itself to be detected. For example, the running characteristics of the motor 12 can be monitored and a possible malfunction or defect in the motor can be detected. If the vibrations that can be detected on the motor increase, this may be an indication of increasing wear on the motor 12 and an imminent failure of the motor 12.

On the basis of the information that can be acquired with the individual sensors 41-44, in particular with the sensors 42-44, a long-term monitoring of the pin lifter 10 or at least parts of it can also be carried out. For this purpose, the acceleration information, in particular frequency spectra and/or acceleration amplitudes, can be recorded and evaluated over a certain period of time. As a result of an overall (algorithmically based) consideration of the recorded information, changes of a specific acceleration characteristic can be recognized and a long-term trend or a tendency for a certain change in the system can be derived from the changes.

With the help of the above long-term view of the system, maintenance of the pin lifting device 10 can be planned in advance depending on an individual load. For example, long-term monitoring of the condition information, particularly taking into account prior known system properties, can be used to estimate a point in time for a possible functional failure on the basis of an increase in a deviation of the acceleration behavior from a target condition. A maintenance time can be set accordingly in an economically optimized manner, i.e. the maintenance is not carried out later than necessary, i.e. before a possible malfunction, and not earlier than necessary to ensure the reliable pin lifting function.

The sensor units 41-44, especially the units 42 and 43, can also be used individually or together to monitor a de-chucking process. De-chucking is a process in which a substrate resting on an electrostatic clamping device (chuck) is to be lifted by one or more pin lifting devices. The voltage between the chuck electrodes, which is responsible for holding the wafer in place, is switched off and the pins are brought into contact with the wafer by extending them.

In a subsequent lifting step, the pressure exerted by the pins on the wafer to lift the wafer increases until the wafer is released from the chuck and is carried only by the pins, i.e. the coupling 32 of the pin lifting device 10 is moved together with the inserted pin by extending it into the carrying position. Based on an acceleration profile that can be recorded, an evaluation or monitoring of the de-chucking process can be provided. A deceleration of the extension movement is to be expected when making contact with the wafer and a subsequent increase in the acceleration values when the wafer is detached from the chuck. A measurable extent of the acceleration (e.g. an amplitude deflection or duration of the deceleration effect) serves as an indicator of whether the de-chucking has taken place under specified conditions. If the measured acceleration profile deviates from a reference profile over a specified tolerance, this indicates faulty detachment or even damage to the wafer.

Appropriate monitoring can be implemented for the placement of the wafer on the support pins. Acceleration at the stylus can be measured by depositing the stylus. This can be compared with a previously known reference and used to derive information regarding a given process reliability.

In a specific embodiment, the information of the sensors 41-44 can be evaluated in a synopsis or processed together. Here, for example, a propagation of vibrations and natural oscillations between the lower drive part and the upper coupling part can be determined.

With such an evaluation, a structural integrity of a corresponding insulating element 21, 22 and thus an insulating effect between the parts can be monitored on the basis of vibration differences between the two parts.

FIGS. 3a and 3b show another embodiment of a pin lifting device 50 according to the invention. FIG. 3a shows a cross-section of this pin lifting device 50, FIG. 3b an exterior view.

A support pin 59 is locked in a coupling 58. The support pin 59 preferably has a metallic, polymer-based or ceramic material, in particular the pin 59 is completely made of such a material. The locking device in the coupling 58 can, for example, be implemented magnetically or by means of clamping.

The coupling 58 can be moved in the z-direction by means of a slide 54. The slide 54 is coupled to a threaded spindle 53 for this purpose, which in turn can be driven by the motor 12.

An optional thermal and electrical insulation between the upper coupling part and the lower drive part is realized in one variant by a first insulating element 52, which thermally and electrically separates an upper housing part from a lower housing part. Preferably, a second insulating element, which can be embodied by the slide 54, can be provided. In this variant of the pin lifting device 50, the threaded spindle 53 is designed and mounted so precisely and rigidly that no (electrically or thermally conductive) contact occurs between the spindle 53 and the coupling 58—even during a relative movement. Alternatively, the spindle 53 is made of or coated with a non-conductive or thermally insulating material. Thus a complete galvanic and thermal separation between the upper and lower part is provided in every condition of the device 50.

In a further variant, both the threaded spindle 53 and the slide 54 located on the spindle 53 can be manufactured as conductive (e.g. metallic). Insulation can then be achieved in particular by means of, for example, an intermediate sleeve between spindle/slide and coupling.

The pin lifter 50 also has a bellows 55 inside the coupling part. The bellows 55 is arranged and shaped in such a way that an atmospheric separation of a process atmosphere region, in which the support pin 59 (pin) is present and a machining process usually takes place, and an external atmosphere region, in which e.g. the drive 12 and further peripheral components can be present, is provided. The bellows 55 is compressed when the pin 59 is extended, wherein the atmospheric separation is maintained. The pin lifting device 50 has two sensor units 45 and 46, each of which is designed as a force sensor.

One of the two sensors 45 is located at pin 59, in the example shown at its lower end which is intended for coupling the pin. Alternatively, the sensor 45 can be attached to another component of the pin lifting device 50, e.g. bellows 55, coupling 58 or between coupling 28 and pin 59 or slide 54, or to another movable element and/or element subjected to an external force during operation. The sensor 45 can alternatively be arranged at the opposite end of pin 59. The arrangement on pin 59 allows direct measurement of a force applied to pin 59 and pin 50 by a substrate to be lifted during lifting, lowering or holding. Such a direct force measurement can also be realized with a sensor between pin 59 and coupling 58, which is preferably assigned to coupling 58 and is not affected by a replacement of pin 59.

The advantage of a sensor 45 provided on pin 59 is that it can be replaced very easily and without any intervention in the pin lifting device 50. An electrical supply of the sensor can be provided, for example, by means of the coupling and corresponding contacts in the coupling 58 or by an energy storage device (e.g. battery or rechargeable battery) in pin 59. Measurement data of the sensor can be transmitted by radio or also by means of corresponding electrical contacts.

One advantage of a sensor provided on the coupling 58 can be the comparatively simple contacting of the sensor for both energy and data transmission.

As a result of the described arrangement of the sensor 45 at the pin and/or at the coupling 58, influences on the force measurement by other components of the pin lifting device can be avoided, thus a force exerted by the bellows 55 or slide 54, for example, is not co-measured and thereby a measuring accuracy concerning a force, which acts between pin 59 and substrate, is increased. If, for example, the bellows 55 were to show signs of wear, this could have a considerable influence on force measurement and lead to an incorrect process evaluation.

The additional force sensor 46 is located at the transition from the motor 12 to the threaded rod 53 and can therefore detect all forces acting on the motor 12 along the threaded rod 53. Thus, a load or required power consumption of the motor 12 can be determined.

The force sensors 45, 46 allow a selective detection of an applied force as well as the detection of a force progression over a certain period of time.

By (continuous) comparison of an applied force level with a stored reference value (e.g. permissible force maximum), process monitoring and recording of the condition of the pin lifting device 50 can be carried out. If the permissible maximum force is exceeded, an appropriate signal can be generated and output, which can indicate an impermissible system load and, if necessary, recommend an inspection of the system.

The maximum allowable force may also be defined for lifting a substrate from an electrostatic clamping device, wherein its exceeding may indicate possible damage to the substrate.

A force curve can be used to determine both a wear phenomenon for one or more components of the pin lifting device and a process quality. The evaluation approaches for the use of an accelerometer (see above) can be transferred to the use of a force sensor for this purpose.

In the event of a measured deviation of the force curve from a reference defined for this purpose, a warning signal can be output. A type of deviation can be evaluated and analyzed for a possible cause. For example, certain patterns of deviation allow conclusions to be drawn about the source of the deviation and/or the effect on the system or pin lift device 50. By means of a long-term observation of a force progression during repeated, similar process steps (process cycles), a trend of a change in the process can also be detected. Trend monitoring also allows a forecast of a future system status and correspondingly optimized planning of maintenance cycles.

The measurement data of the force sensor 45 or 46 also allow a comparison with a measurement of the motor current, i.e. a comparison of a torque provided by the motor 12 with an applied force. This provides mutual calibration and monitoring of both measuring principles.

FIG. 3b shows an exterior view of the pin lifter 50. The pin 59 protrudes from the upper side of the housing of the lifter 50. A fixing element 52 of the insulating component galvanically and thermally separates the lower drive part from the upper coupling part or its respective housing parts and parts that are translatorily immovable in order to prevent the transmission of excited vibrations and oscillations.

The pin lifter 50 has two additional accelerometers 47, 48 on its outer housing side. One sensor 47 is located on the upper coupling part, the other sensor 48 on the lower drive part. For example, a transmission of vibrations and oscillations between the two housing parts as well as a possible transmission from the drive of the pin lifter 50 to a connected process chamber can be detected.

In addition to the functions described above, such an arrangement can also be used, for example, to monitor the desired insulating effect of the insulating element 52, for example.

It is understood that the figures shown only schematically represent possible embodiment examples. The different approaches can be combined according to the invention with each other as well as with devices for substrate movement in prior art vacuum process chambers, especially pin lifters.

1. A pin lifting device, which is designed for moving and positioning a substrate to be processed, in particular a wafer, in a process atmosphere region (P) which can be provided by a vacuum process chamber, comprising:
a coupling designed to receive a support pin adapted to contact and support the substrate, and
a drive unit which is designed and interacts with the coupling in such a way that the coupling is linearly adjustable along an adjustment axis (A) from
a lowered normal position, in particular for providing the support pin in a condition substantially free of action with respect to its intended effect, into
an extended support position, in particular for providing the intended effect of receiving and/or providing the substrate by the support pin, and back again,
wherein
the pin lifting device has at least one sensor unit, which is designed and arranged in such a way that, by means of the sensor unit, a force-dependent and/or acceleration-dependent condition information can be generated with reference to at least a part of the pin lifting device.

2. The pin lifting device according to claim 1,
wherein
the sensor unit comprises at least one of the following inertial sensors for generating the acceleration-dependent condition information:
an acceleration sensor which detects accelerations along at least one axis aligned in a defined manner, and/or
a rotation rate sensor which detects rotation speeds or rotation accelerations about at least one axis aligned in a defined manner.

3. The pin lifting device according to claim 1,
wherein
the sensor unit comprises at least one of the following force sensors for generating the force-dependent condition information:
a pressure sensor,
a deformation-sensitive element, in particular a strain gauge,
a piezo force transducer with a piezo ceramic element,
an electrodynamic force transducer,
a resistive force transducer,
a vibration force transducer and/or
a spring body force transducer.

4. The pin lifting device according to claim 1, wherein the sensor unit is arranged on
the coupling, in particular on a receptacle for the support pin,
the drive unit, in particular on a spindle or a moto of the drive unit,
a coupling element which provides the cooperation of the drive unit with the coupling, in particular a threaded rod,
the support pin and/or
a housing of the pin lifting device, in particular on an underside or on an inner wall of the housing.

5. The pin lifting device according to claim 1, wherein the lifting pin device is incorporated in a system, the system comprising:
the pin lifting device and a processing and control unit, wherein the processing and control unit is configured:
to obtain and/or process the condition information of the sensor unit, and
to generate an output dependent on the condition information,
wherein the pin lifting device, which is designed for moving and positioning a substrate to be processed, in particular a wafer, in a process atmosphere region (P) which can be provided by a vacuum process chamber, having
a coupling designed to receive a support pin adapted to contact and support the substrate, and
a drive unit which is designed and interacts with the coupling in such a way that the coupling is linearly adjustable along an adjustment axis (A) from
a lowered normal position, in particular for providing the support pin in a condition substantially free of action with respect to its intended effect, into
an extended support position, in particular for providing the intended effect of receiving and/or providing the substrate by the support pin, and back again,
and wherein the pin lifting device has at least one sensor unit, which is designed and arranged in such a way that, by means of the sensor unit, a force-dependent and/or acceleration-dependent condition information can be generated with reference to at least a part of the pin lifting device.

6. The system according to claim 5,
wherein
the processing and control unit is designed to provide the output relating to a current condition or a current normal condition deviation of the drive unit and/or the coupling by means of processing the condition information, in particular visually or acoustically, in particular wherein the output is generated by means of an actual/target comparison for the detected condition information.

7. The system according to claim 5,
wherein
the output is provided with respect to a mechanical and/or structural integrity of the drive unit and/or the coupling, in particular wherein the output comprises one or both of:
a warning of increased wear of a component of the pin lifting device, and
a prediction of the durability of a component of the pin lifting device.

8. The system according to claim 5,
wherein
the processing and control unit is designed to provide a frequency spectrum based on the condition information.

9. The system according to claim 5,
wherein
the processing and control unit is designed to provide, based on an analysis of the condition information with respect to one or more measured value frequencies, the output with respect to a localization of an oscillation causing the respective measured value frequency.

10. The system according to claim 5,
wherein
the processing and control unit is designed to provide, based on a comparison of the condition information with a predefined reference value, the signal relating to an evaluation of a process performed with the pin lifting device.

11. The system according to claim 5,
wherein
the processing and control unit is designed to derive a condition trend, in particular a long-term trend, for a system condition and/or a change in the system condition based on multiple acquisitions of the condition information, in particular wherein the condition information is acquired periodically, in particular continuously, during a specific time period and a frequency spectrum and/or a force-displacement ratio is derived.

12. The system according to claim 5,
wherein
the processing and control unit is designed to provide a calibration of the sensor unit and/or a monitoring of the sensor-unit-independent condition information based on a comparison of a currently detected condition information with further sensor-unit-independent condition information, in particular the motor current of the drive unit.

13. The system according to claim 5,
wherein
the processing and control unit is designed to detect by means of the sensor unit, during an extension movement of the coupling equipped with a support pin into the support position, a change in condition, in particular an increase in force due to a contacting of the substrate and/or acceleration course on the support pin, and to link it, in particular, to an extension position.

14. The system according to claim 5,
wherein
the sensor unit is designed and arranged in such a way that an acceleration which occurs in the drive unit and/or acts from the outside on the pin lifting device can be detected as condition information.

15. The system according to claim 5,
wherein
the sensor unit is designed and arranged in such a way that an acceleration which is produced by frictional vibration at at least one of the following locations can be detected as condition information:
between at least a part of the coupling and a guide and/or a bearing for the coupling,
between at least a part of the coupling and at least a part of the drive unit, and
between at least a part of the drive unit and a guide and/or a bearing for the drive unit.

16. The system according to claim 5,
wherein
the condition information comprises at least one of the following information items:
a force acting on the coupling and/or the support pin, in particular generated by the weight force of a substrate resting on the support pin,
a force acting on the drive unit, in particular on a drive shaft or a motor of the drive unit,
an acceleration generated on the coupling and/or the support pin,
an acceleration generated at the drive unit,
an acceleration condition or a change in acceleration of the pin lifting device.

17. The system according to claim 5,
wherein
the processing and control unit is designed to generate a control signal as an output based on the condition information, and
the drive unit is arranged and designed
to obtain the control signal and
to adjust the coupling between the normal position and the support position depending on the control signal.

18. The system according to claim 17, wherein
the processing and control unit is set up such that the control signal can be set automatically as a function of current condition information.
